(19) United States
(12) Patent Application Publication
(10) Pub. No.: US 2026/0255866 A1
(43) Pub. Date: Aug. 27, 2026

(54) DISPLAY DEVICE AND ELECTRONIC DEVICE INCLUDING THE SAME

(71) Applicant: Samsung Display Co., LTD., Yongin-si (KR)

(72) Inventors: Da Som GU, Yongin-si (KR); Ji Hoon KIM, Yongin-si (KR); Do Hoon KIM, Yongin-si (KR); Sun Je PARK, Yongin-si (KR); Sung Guk AN, Yongin-si (KR); Chul Ho JEONG, Yongin-si (KR); Kyung Min CHOI, Yongin-si (KR)

(21) Appl. No.: 19/545,205

(22) Filed: Feb. 20, 2026

(30) Foreign Application Priority Data
Feb. 21, 2025 (KR) 10-2025-0023063

(51) Int. Cl. H10K 77/10

(52) U.S. Cl. CPC H10K 77/10

(57) ABSTRACT

A display device includes a display panel; an upper buffer structure on the display panel, and a lower buffer structure disposed under the display panel. The upper buffer structure includes an upper substrate, and upper buffer patterns arranged on a surface of the upper substrate. The lower buffer structure includes a lower substrate, and lower buffer patterns arranged on a surface of the lower substrate and having a storage modulus greater than a storage modulus of the upper buffer patterns.

This application claims priority to Korean Patent Application No. 10-2025-0023063, filed on Feb. 21, 2025, and all the benefits accruing therefrom under 35 U.S.C. §119, the content of which in its entirety is herein incorporated by reference.

### BACKGROUND

### 1. Field

Embodiments of the disclosure relate to a display device and an electronic device. More particularly, embodiments of the disclosure relate to a display device including a display panel and functional layers, and an electronic device including the same.

### 2. Descriptions of the Related Art

In a display device such as an organic light-emitting diode (“OLED”) display device and a liquid crystal display (“LCD”) device, a display substrate including thin film transistors (“TFTs”) and various wirings may be included. A display structure including electrodes and emission layers may be formed on the display substrate to provide a display panel.

A window cover may be attached to the display panel, and lower structures such as a supporting plate and a cover panel may be disposed under the display panel.

However, mechanical damages to the display panel may occur due to external impact and folding/bending applied to the display device.

### SUMMARY

According to a feature of the disclosure, there is provided a display device having improved structural and mechanical reliability.

According to a feature of the disclosure, there is provided an electronic device having improved structural and mechanical reliability.

A display device may include a display panel, an upper buffer structure on the display panel, and a lower buffer structure under the display panel. The upper buffer structure may include an upper substrate, and upper buffer patterns arranged on a surface of the upper substrate. The lower buffer structure may include a lower substrate, and lower buffer patterns arranged on a surface of the lower substrate and having a storage modulus greater than a storage modulus of the upper buffer patterns.

In an embodiment, the upper buffer patterns may include first upper buffer patterns arranged on a top surface of the upper substrate, and second upper buffer patterns arranged on a bottom surface of the upper substrate.

In an embodiment, a width or an interval of the first upper buffer patterns may be different from a width or an interval of the second upper buffer patterns.

In an embodiment, the lower buffer patterns may include first lower buffer patterns arranged on a top surface of the lower substrate, and second lower buffer patterns arranged on a bottom surface of the lower substrate.

In an embodiment, a width or an interval of the first lower buffer patterns may be different from a width or an interval of the second lower buffer patterns.

In an embodiment, a width of the upper buffer patterns may be less than a width of the lower buffer patterns.

In an embodiment, a thickness of the upper buffer patterns may be greater than a thickness of the lower buffer patterns.

In an embodiment, an interval between the upper buffer patterns may be equal to or greater than a width of each of the upper buffer patterns.

In an embodiment, an interval between the lower buffer patterns may be equal to or greater than a width of each of the lower buffer patterns.

In an embodiment, the upper buffer structure may further include sub-upper buffer patterns arranged on an outer portion of the surface of the upper substrate, and a storage modulus of the sub-upper buffer patterns may be greater than a storage modulus of the upper buffer patterns.

In an embodiment, the display device may have a folding area and a non-folding area. The upper buffer structure may further include sub-upper buffer patterns arranged on a portion of the surface of the upper substrate in the non-folding area. The upper buffer patterns may be arranged on a portion of the surface of the upper substrate in the folding area, and may have the storage modulus less than a storage modulus of the sub-upper buffer patterns.

In an embodiment, the display device may have a folding area and a non-folding area. The lower buffer structure may further include sub-lower buffer patterns arranged on a portion of the surface of the lower substrate in the folding area together with the lower buffer patterns. A storage modulus of the sub-lower buffer patterns may be less than the storage modulus of the lower buffer patterns.

In an embodiment, the display device may have a folding area and a non-folding area. The lower buffer patterns may be arranged on a portion of the surface of the lower substrate in the folding area.

In an embodiment, the number of the lower buffer patterns arranged on a folding axis of the folding area may be greater than the number of the lower buffer patterns arranged on a side portion of the folding area next (adjacent) to the non-folding area.

In an embodiment, the storage modulus of the upper buffer patterns at 25 degrees Celsius (° C) may be 0.1 megapascal (MPa) or less, and the storage modulus of the lower buffer patterns at 25° C may be 0.4 MPa or greater.

A display device may include a display panel, an upper buffer structure on the display panel, and a lower buffer structure under the display panel. The upper buffer structure may include an upper substrate, upper buffer patterns arranged on a surface of the upper substrate, and sub-upper buffer patterns arranged on the surface of the upper substrate together with the upper buffer patterns and having a storage modulus different from a storage modulus of the upper buffer patterns. The lower buffer structure may include a lower substrate, lower buffer patterns arranged on a surface of the lower substrate, and sub-lower buffer patterns arranged on the surface of the lower substrate together with the lower buffer patterns and having a storage modulus different from a storage modulus of the lower buffer patterns.

In an embodiment, the sub-upper buffer patterns may be arranged on an outer portion of the surface of the upper substrate, and may have the storage modulus greater than the storage modulus of the upper buffer patterns.

In an embodiment, the display device may have a folding area and a non-folding area. The sub-lower buffer patterns may be arranged on a portion of the surface of the lower substrate in the folding area together with the lower buffer patterns. The storage modulus of the sub-lower buffer patterns may be less than the storage modulus of the lower buffer patterns.

An electronic device may include a display device, a memory, and a processor executing data included in the memory to control an operation of the display device. The display device may include a display panel, an upper buffer structure on the display panel, and a lower buffer structure under the display panel. The upper buffer structure may include an upper substrate, and upper buffer patterns arranged on a surface of the upper substrate. The lower buffer structure may include a lower substrate, and lower buffer patterns arranged on a surface of the lower substrate and having a storage modulus greater than a storage modulus of the upper buffer patterns.

In an embodiment, the electronic device may include virtual reality or augmented reality glasses, a smartphone, a tablet personal computer, a laptop, a television (“TV”), a desk monitor, smart glasses, a head-mounted display, a smart watch, or a vehicle display.

In a display device in embodiments of the disclosure, an upper buffer structure may be disposed on a display panel, and a lower buffer structure may be disposed on a display panel under the display panel. The upper buffer structure and the lower buffer structure may include buffer patterns having different storage modulus (G′). Impact damping properties may be improved on the display panel, and impact resistance properties may be improved under the display panel by the buffer patterns.

### BRIEF DESCRIPTION OF THE DRAWINGS

The above and other embodiments, advantages and features of this disclosure will become more apparent by describing in further detail embodiments thereof with reference to the accompanying drawings.

FIG. 1 is an exploded perspective view illustrating embodiments of a display device or an electronic device.

FIGS. 2 and 3 are a schematic plan view and a schematic cross-sectional view, respectively, illustrating embodiments of a display panel.

FIG. 4 is a schematic cross-sectional view illustrating embodiments of a display device.

FIGS. 5 and 6 are cross-sectional views illustrating embodiments of buffer structures.

FIGS. 7 and 8 are a plan view and a cross-sectional view, respectively, illustrating embodiments of an upper buffer structure.

FIG. 9 is a plan view illustrating embodiments of an upper buffer structure.

FIGS. 10 and 11 are a plan view and a cross-sectional view, respectively, illustrating embodiments of a lower buffer structure.

FIGS. 12 and 13 are plan views illustrating embodiments of a lower buffer structure.

FIG. 14 is a block diagram of an embodiment of an electronic device.

FIG. 15 is a schematic diagram of embodiments of electronic devices.

### DETAILED DESCRIPTION

Hereinafter, embodiments of the disclosure will be described in more detail with reference to the attached drawings. The same reference numerals may be used for indicating the same elements in the drawings, and repeated descriptions of the same elements may be omitted. Embodiments disclosed in the attached drawings are exemplary, and is to be understood to include all modifications, equivalents and substitutes included in the spirit and technical scope of the disclosure.

The terms "on", "connected", "coupled," etc., used herein refers to a direct placement/connection/combination, and also refers to a case where another element is interposed two different elements.

The terms such as "first", "second", "below", "lower", "upper", "above," etc., are used in a relative sense to distinguish different elements or positions, and do not specify an absolute position or an absolute order.

The term "adhesive" used herein encompasses both a pressure-sensitive adhesive layer or material, and a bonding layer or material.

In the disclosure, terms "top (or upper)" and "bottom (or lower)" may be classified based on a direction from a housing HS to a window structure WS.

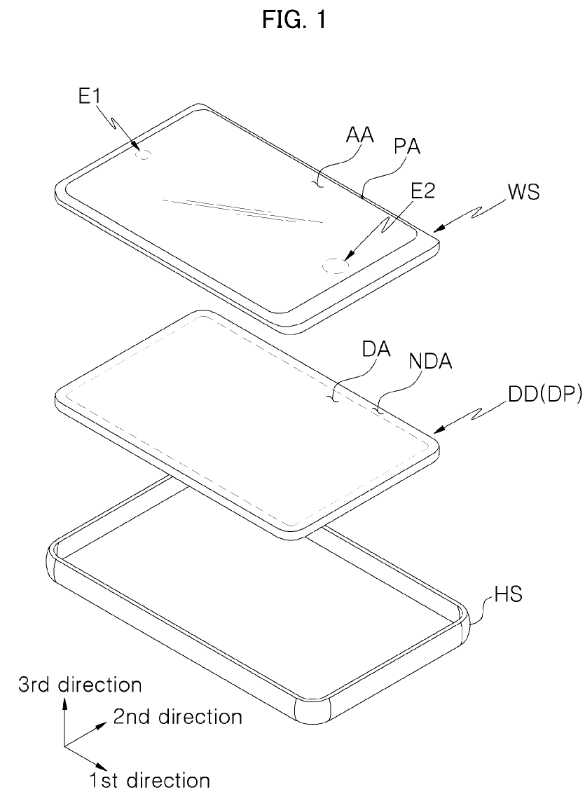

FIG. 1 is an exploded perspective view illustrating embodiments of a display device or an electronic device.

In FIG. 1, a first direction and a second direction may refer to two directions parallel to a display surface of a display device DD or a display panel DP and perpendicular to each other. In an embodiment, the first direction may correspond to an X-direction (a row direction), and the second direction may correspond to a Y-direction (a column direction) of the display device, for example.

A third direction may be perpendicular to the first direction and the second direction. The third direction may correspond to a Z-direction (a thickness direction) of the display device.

The definitions of the directions described above may be equally applied to the accompanying drawings.

Referring to FIG. 1, the electronic device may be implemented in the form of a mobile phone (smart phone), a tablet, a personal computer, or the like, including a display device.

The electronic device may include a window structure WS, the display device DD, and a housing HS. The housing HS, the display panel DP (or the display device DD), and the window structure WS may be sequentially stacked along the third direction.

The display device DD may include a liquid crystal display (“LCD”) device, an organic light-emitting diode (“OLED”) display device, a quantum dot light-emitting diode (“QLED”) display device, or the like. In an embodiment, the display device DD may be an organic light-emitting diode (“OLED”) display device including an organic emission layer.

The window structure WS may provide an external display surface recognized by a user, such as a viewing surface of a mobile phone, and may include a transparent material film. In an embodiment, the window structure WS may include glass (e.g., ultra-thin glass (“UTG”)), a hard coating film, a plastic film, or the like, for example.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area or a black matrix area of the electronic device.

The display device DD or the display panel DP may include a display area DA and a non-display area NDA. The display area DA of the display panel DP may substantially correspond to or overlap the active area AA of the window structure WS.

The non-display area NDA of the display panel DP may substantially correspond to or overlap the peripheral area PA of the window structure WS. In an embodiment, the peripheral area PA of the window structure WS may include a margin area that does not overlap the display panel DP.

In an embodiment, functional device areas E1 and E2 may be included in the active area AA of the window structure WS. In an embodiment, a first functional device area E1 may be included at one end portion of the active area AA and may be implemented, e.g., in the form of a camera hole, for example. The second functional device area E2 may serve as a fingerprint sensing area.

In an embodiment, a sensor structure for a touch sensing or a fingerprint sensing may be disposed in the display panel DP or between the window structure WS and the display panel DP, for example.

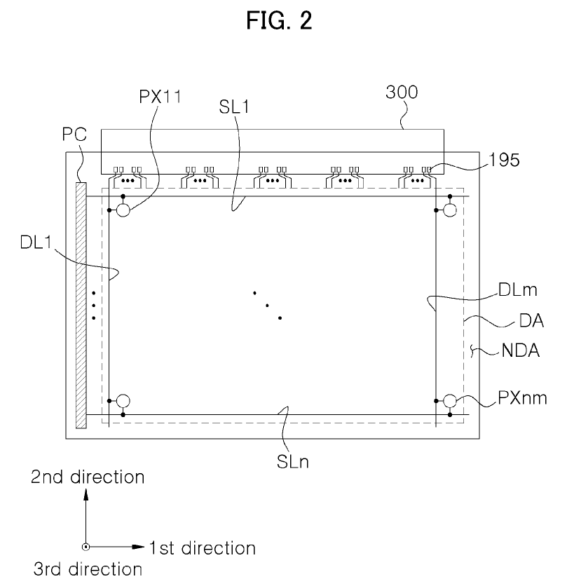

The housing HS may serve as a frame structure or a rear housing of the display device DD or the electronic device. A cover panel may be disposed between the housing HS and the display panel DP. The housing HS or the cover panel may include a plate (e.g., an SUS plate) that supports the display panel DP, the printed circuit board 300 (refer to FIG. 2), or the like. The housing HS or the cover panel may include an elastic body for absorbing shock of the display device DD.

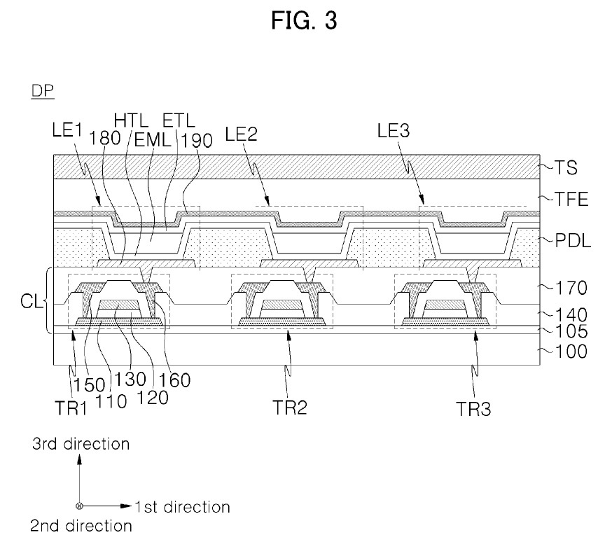

FIGS. 2 and 3 are a schematic plan view and a schematic cross-sectional view, respectively, illustrating embodiments of a display panel.

Referring to FIG. 2, a plurality of pixels PX11 to PXnm may be arranged in a display area DA of the display panel DP. Here, n and m are natural numbers.

In an embodiment, a pixel circuit including scan lines (or gate lines SL1 to SLn) forming first to nth rows and data lines DL1 to DLm forming first to mth columns may be arranged on a base substrate 100 of the display device. Each of the pixels PX11 to PXnm may be connected to a scan line of a corresponding row among a plurality of scan lines SL1 to SLn and a data line of a corresponding column among a plurality of data lines DL1 to DLm.

Each of the pixels PX11 to PXnm may further include a pixel driving circuit including a transistor and a light-emitting device as described below. Although not illustrated in detail in FIG. 2, the pixel circuit may further include wirings such as a power line, a ground line, or the like.

In FIG. 2, data lines DL1 to DLm extend in the second direction, and scan lines SL1 to SLn extend in the first direction, but the inventive concepts are not limited to the construction illustrated in FIG. 2.

A peripheral circuit PC may be disposed in the non-display area NDA corresponding to a peripheral area with respect to the display area DA. In an embodiment, the peripheral circuit PC may include a gate driving circuit, for example. The gate driving circuit may be integrated into the display device by an oxide semiconductor gate (“OSG”) driver circuit process, an amorphous silicon gate (“ASG”) driver circuit process, or a polysilicon gate (“PSG”) driver circuit process.

The peripheral circuit PC may further include a data driver, a gate driver, a light-emitting driver, a power voltage generator, a timing controller, or the like.

The display device DD may further include a printed circuit board 300. Pads 195 of the pixel circuit may be assembled at one side portion of the non-display area NDA. A printed circuit board 300 may be electrically connected to the pixel circuit through the pads 195. In an embodiment, the printed circuit board 300 may be electrically connected to the pads 195 by a heating-compression process using a conductive intermediate structure such as an anisotropic conductive film ( “ACF”), for example.

An integrated circuit (“IC”) such as a data driving circuit may be disposed on the printed circuit board 300. In an embodiment, an integrated circuit (“IC”) chip in the form of a chip-on-film (“COF”) may be disposed (e.g., mounted) on the printed circuit board 300.

Referring to FIG. 3, the display panel DP may include a base substrate 100, a circuit layer CL stacked on the base substrate 100, and a light-emitting device disposed on the circuit layer CL.

The base substrate 100 may serve as a back-plane substrate of a display device. A glass substrate or a plastic substrate may be used as the base substrate 100.

In an embodiment, the base substrate 100 may include a polymer material having transparency and flexibility. In this case, the base substrate 100 may be used in a transparent flexible display device. In an embodiment, the base substrate 100 may include a polymer material such as polyimide, polysiloxane, an epoxy resin, an acrylic resin, polyester, or the like, for example. In an embodiment, the base substrate 100 may include polyimide.

The circuit layer CL may include transistors TR1, TR2 and TR3. The circuit layer CL may include wiring layers and insulation layers forming a thin film transistor array TFT-Array.

The circuit layer CL may further include a buffer layer 105 formed on a top surface of the base substrate 100. Moisture penetrating through the base substrate 100 may be blocked by the buffer layer 105, and diffusion of impurities between the base substrate 100 and structures formed on the base substrate 100 may also be blocked by the buffer layer 105.

The buffer layer 105 may include, e.g., an inorganic insulating material such as silicon oxide, silicon nitride, or silicon oxynitride. These may be used alone or in any combinations thereof. In an embodiment, the buffer layer 105 may have a stacked structure including a silicon oxide layer and a silicon nitride layer.

The buffer layer 105 may be formed by a deposition process such as a chemical vapor deposition (“CVD”) process, a sputtering process, an atomic layer deposition (“ALD”) process, or the like, to include the inorganic insulating material described above.

The transistors TR1, TR2, and TR3 may be disposed on the buffer layer 105. The first transistor TR1, the second transistor TR2, and the third transistor TR3 may be electrically connected to a first light-emitting device LE1, a second light-emitting device LE2, and a third light-emitting device LE3, respectively.

Each of the transistors TR1, TR2 and TR3 may include an active layer 110, a gate insulating layer 120, and a gate electrode 130.

The active layer 110 may be disposed on the buffer layer 105, and may be patterned by, e.g., a photo-lithography process to be repeatedly/regularly arranged at each pixel. The active layer 110 may include a silicon compound such as polysilicon or amorphous silicon. A p-type dopant or an n-type dopant may be doped in a partial region of the active layer 110, so that the active layer 110 may include a source region, a drain region, and a channel region.

The active layer ACT may include an oxide semiconductor such as indium gallium zinc oxide (“IGZO”), zinc tin oxide (“ZTO”), or indium tin zinc oxide (“ITZO”).

The gate insulating layer 120 may be formed on the active layer 110, and the gate electrode 130 may be stacked on the gate insulating layer 120. As illustrated in FIG. 3, the gate insulating layer 120 may be formed in a pattern shape partially covering each active layer 110. In an alternative embodiment, the gate insulating layer 120 may extend continuously throughout a plurality of pixels or light-emitting regions, and may be provided commonly in the first to third transistors TR1, TR2 and TR3.

The gate electrode 130 may overlap the channel region of the active layer ACT in a vertical direction. A scan signal may be transmitted from the scan line through the gate electrode 130.

The gate insulating layer 120 may be formed by the above-mentioned deposition process to include an inorganic insulating material such as silicon oxide, silicon nitride, silicon oxynitride, or the like. In an embodiment, the gate insulating layer 120 having the pattern shape as illustrated in FIG. 3 may be formed by a photo-lithography process using the gate electrode 130 as an etching mask

In an embodiment, the gate electrode 130 and the gate insulating layer 120 may be used as ion implantation masks to form the source region and the drain region in the active layer 110.

An insulating interlayer 140 covering the gate insulating layer 120 and the gate electrode 130 may be formed on the active layer 110. Connection electrodes 150 and 160 which may be in contact with or electrically connected to the active layer 110 may be formed on the insulating interlayer 140.

The insulating interlayer 140 may be formed through the above-described deposition process to include an inorganic insulating material such as silicon oxide, silicon nitride, silicon oxynitride, or the like. The insulating interlayer 140 may be formed in a single-layered structure or a multi-layered structure including different materials from each other.

In an embodiment, when the active layer 110 includes an oxide semiconductor, hydrogen (H) contained in the insulating interlayer 140 may be diffused or transferred to vacancy sites induced in the active layer 110 when forming the gate insulating layer 120. Accordingly, a carrier concentration may be increased by hydrogen, so that the source region and the drain region having increased conductivity may be formed at the side portions of the active layer 110.

The connection electrodes 150 and 160 may extend through the insulating interlayer 140 to be connected to the active layer 110. When the gate insulating layer 120 is continuously formed in common in a plurality of pixel regions, the connection electrodes 150 and 160 may also extend through the gate insulating layer 120.

The connection electrodes 150 and 160 may include a source electrode 150 connected to or in contact with the source region of the active layer 110 and a drain electrode 160 connected to or in contact with the drain region of the active layer 110.

Contact holes may be formed by partially etching the insulating interlayer 140. In an embodiment, the contact holes exposing the source region and the drain region, respectively, may be formed, for example. A metal layer filling the contact holes may be formed on the insulating interlayer 140, and then may be partially etched to form the source electrode 150 and the drain electrode 160. In an embodiment, the source electrode 150 may be connected to the above-described data line, for example.

The gate electrode 130 and the connection electrodes 150 and 160 may include a metal such as Ag, Mg, Al, W, Cu, Ni, Cr, Mo, Ti, Pt, Ta, Nd, Sc, or the like, any alloys thereof, or a nitride thereof. The gate electrode 130 and the connection electrodes 150 and 160 may be formed by the above-described deposition process and the photo-lithography process.

A planarization layer 170 covering the connection electrodes 150 and 160 may be formed on the insulating interlayer 140. The planarization layer 170 may accommodate a via structure electrically connecting a pixel electrode 180 and the drain electrode 160.

In an embodiment, the planarization layer 170 may include an organic material such as polyimide, an epoxy resin, an acrylic resin, polyester, a siloxane resin, benzocyclobutene (“BCB”), or the like. The planarization layer 170 may be formed by the above-described deposition process or a spin coating process.

The pixel electrode 180 may be formed in each pixel to be electrically connected to the transistors TR1, TR2 and TR3. The pixel electrode 180 may be formed on the planarization layer 170 to be electrically connected to the drain electrode 160.

In an embodiment, the planarization layer 170 may be partially etched to form a via hole exposing a top of the drain electrode 160, for example. A conductive layer including a metal or a transparent conductive oxide and filling the via hole may be formed on a top surface of the planarization layer 170, and the conductive layer may be etched to form the pixel electrode 180.

The pixel electrode 180 may be provided as an anode, and may include a relatively high work function conductive material capable of promoting hole injection. The pixel electrode 180 may be formed as a transmissive electrode. The pixel electrode 180 may include a transparent conductive oxide such as indium tin oxide (“ITO”), indium zinc oxide (“IZO”), zinc oxide (ZnO), indium tin oxide (“ITZO”), or the like.

The pixel electrode 180 may be formed as a translucent electrode or a reflective electrode. The pixel electrode 180 may include a metal selected from Ag, Mg, Cu, Al, Pt, Pd, Au, Ni, Nd, Ir, Cr, Li, Ca, Mo, Ti, W, In, Sn and Zn, or an alloy or a compound (e.g., LiF) including at least one therefrom.

The pixel electrode 180 may have a single-layered structure or a multi-layered structure. In an embodiment, the pixel electrode 180 may have a triple-layered structure such as ITO/Ag/ITO or ITO/Al/ITO, for example.

A pixel defining layer PDL, a light-emitting portion, and a counter electrode 190 may be disposed on the circuit layer CL. The light-emitting devices LE1, LE2, and LE3 may be defined by the pixel electrode 180, the light-emitting portion, and the counter electrode 190.

The pixel defining layer PDL may be formed on the planarization layer 170 to expose a top surface of the pixel electrode 180. A light-emitting region may be defined by a sidewall of the pixel defining layer PDL. A red light-emitting region, a green light-emitting region, and a blue light-emitting region may be separated and defined by the pixel defining layer PDL, and the first light-emitting device LE1, the second light-emitting device LE2, and the third light-emitting device LE3 may correspond to a blue light-emitting device, a green light-emitting device, and a red light-emitting device, respectively.

In an embodiment, all of the light-emitting devices LE1, LE2 and LE3 may be white light-emitting devices or blue light-emitting devices.

The light-emitting portion may be disposed in each light-emitting region formed by the pixel defining layer PDL. In an embodiment, the light-emitting portion may include an emission layer EML including an organic light-emitting material. The emission layer EML may include an organic light-emitting material. In an embodiment, the emission layer EML includes a fluorescent host and/or a host for a phosphorescent device, and may further include a fluorescent dopant, a phosphorescent dopant, and/or a thermally activated delayed fluorescent (“TADF”) dopant, for example.

In an embodiment, the light-emitting portion may be formed by a process such as a thermal deposition, a vapor deposition, a vacuum deposition, a spin coating, an inkjet printing, a laser printing, a casting, a laser thermal transfer, or the like, for example.

The counter electrode 190 may be disposed on a top surface of the pixel defining layer PDL and the light-emitting portions. The counter electrode 190 may be a common electrode that is continuously provided commonly in a plurality of the light-emitting regions or pixels.

The counter electrode 190 may be provided as an electron injection electrode or a cathode. The counter electrode 190 may include a metal, an alloy, an electrically conductive compound, or the like, having a relatively low work function.

In an embodiment, the counter electrode 190 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like, for example. These may be used alone or in a combination of two or more therefrom.

The counter electrode 190 may be formed as a transmissive electrode, a translucent electrode, or a reflective electrode. The counter electrode 190 may have a single-layered structure or a multi-layered structure.

The light-emitting portion may further include a hole transport layer HTL and an electron transport layer ETL. In an embodiment, the hole transport layer HTL, the emission layer EML, the electron transport layer ETL and the counter electrode 190 may be sequentially stacked from the top surface of the pixel electrode 180.

In an embodiment, the hole transport layer HTL may include a hole transporting material such as 4,4',4"-[tris(3-methylphenyl)phenylamino] triphenylamine (“m-MTDATA”), 4,4'4"-tris(N,N-diphenylamino)triphenylamine (“TDATA”), 4,4',4"-tris[N(2-naphthyl)-N-phenylamino]-triphenylamine (“2-TNATA”), N,N'-di(naphthalene-l-yl)-N,N'-diphenyl-benzidine (“NPB”), N,N'-bis(3-methylphenyl)-N,N'-diphenyl-[1,1'-biphenyl]-4,4'-diamine (“TPD”), 4,4',4"-tris(N-carbazolyl)triphenylamine (“TCTA”), poly(3,4-ethylenedioxythiophene)/poly(4-styrenesulfonate) (“PEDOT/PSS”), or the like, for example.

In an embodiment, the electron transport layer ETL may include an electron transporting material such as an anthracene-based compound, Alq3 (tris(8-hydroxyquinolinato)aluminum), 1,3,5-Tri(1-phenyl-1H-benzo[d]imidazol-2-yl)benzene (“TPBi”), 2,9-dimethyl-4,7-diphenyl-1,10-phenanthroline (“BCP”), 4,7-diphenyl-1,10-phenanthroline (“Bphen”), 3-(4-biphenylyl)-4-phenyl-5-tert-butylphenyl-1,2,4-triazole (“TAZ”), 4-(naphthalen-1-yl)-3,5-diphenyl-4H-1,2,4-triazole (“NTAZ”), 2-(4-biphenylyl)-5-(4-tert-butylphenyl)-1,3,4-oxadiazole (“tBu-PBD”), bis(2-methyl-8-quinolinolato-N1,O8)-(1,1'-biphenyl-4-olato)aluminum (“BAlq”), or the like, for example.

In an embodiment, a hole injection layer may be further formed between the pixel electrode 180 and the hole transport layer HTL. An electron injection layer may be further formed between the counter electrode 190 and the electron transport layer ETL.

In an embodiment, the emission layer EML may be patterned to be disposed within the light-emitting region defined by the pixel defining layer PDL. Accordingly, the light-emitting portions may be separated from each other in the form of an island to be spaced apart from each other at each of a plurality of pixels.

In an embodiment, the layers included in the above-described light-emitting portion may continuously and commonly extend over the plurality of pixels and the top surface of the pixel defining layer PDL. In an embodiment, the hole transport layer HTL and the electron transport layer ETL may be included as a common layer for the light-emitting devices LE1, LE2, and LE3, for example.

In an embodiment, an encapsulation layer TFE covering the light-emitting devices LE1, LE2 and LE3 may be disposed on the display panel DP. In an embodiment, the encapsulation layer TFE may be included as an element of the display panel DP.

The encapsulation layer TFE may be disposed on the pixel defining layer PDL and the light-emitting devices LE1, LE2 and LE3 to protect the light-emitting devices LE1, LE2 and LE3 from moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (“AGE”)), or any combination thereof; or a combination of the inorganic and organic layers.

The encapsulation layer TFE may be formed in a single-layered structure or a multi-layered structure. In an embodiment, the encapsulation layer TFE may have a sequential stacked structure of a first inorganic layer, an organic layer and a second inorganic layer.

In an embodiment, a color control layer overlapping the light-emitting portion or the emission layer EML may be disposed on the encapsulation layer TFE. The color control layer may include a color conversion layer including quantum dots and/or a color filter.

In an embodiment, a touch sensor layer TS may be disposed on the encapsulation layer TFE. The touch sensor layer TS may include a sensor substrate layer and sensor electrodes arranged on the sensor substrate layer. The touch sensor layer TS may be directly stacked on the encapsulation layer TFE as an on-cell type sensor. An adhesive layer may be disposed between the touch sensor layer TS and the encapsulation layer TFE.

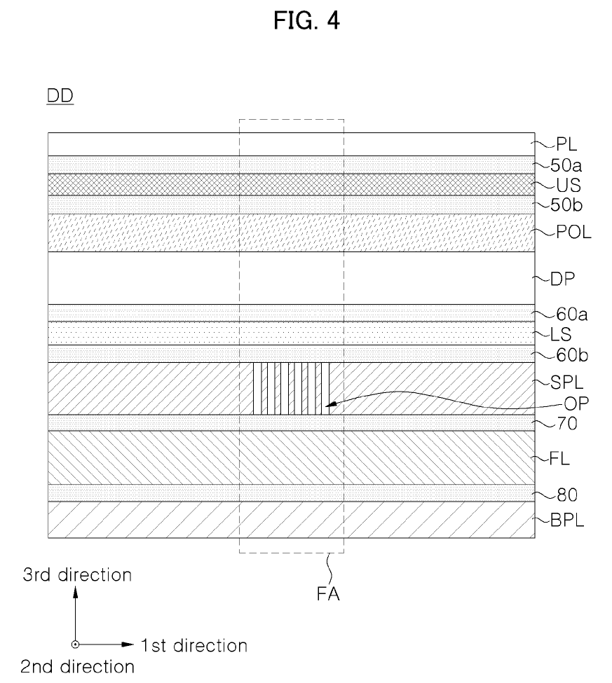

FIG. 4 is a schematic cross-sectional view illustrating embodiments of a display device.

Referring to FIG. 4, the display device DD may include the display panel DP as described above, an upper buffer structure US stacked on the display panel DP, and a lower buffer structure LS disposed under the display panel DP.

A first upper adhesive layer 50a and a second upper adhesive layer 50b may be formed on top and bottom surfaces of the upper buffer structure US, respectively. The first upper adhesive layer 50a and the second upper adhesive layer 50b may be included as elements of the upper buffer structure US.

A first lower adhesive layer 60a and a second lower adhesive layer 60b may be formed on top and bottom surfaces of the lower buffer structure LS, respectively. The first lower adhesive layer 60a and the second lower adhesive layer 60b may be included as elements of the lower buffer structure LS.

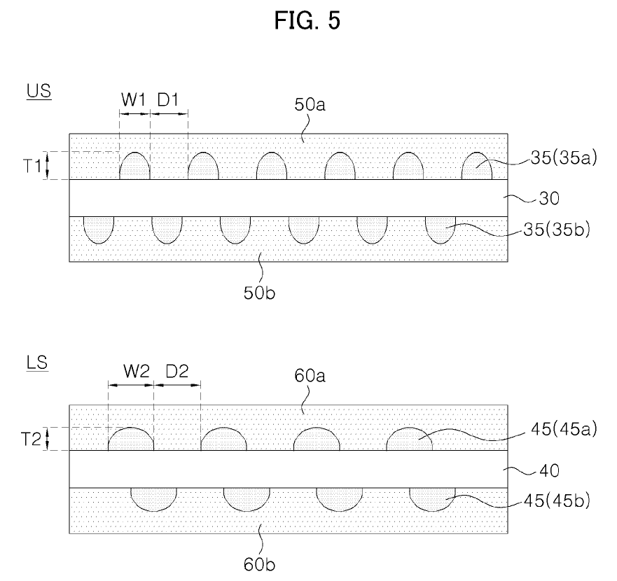

The elements and structures of the upper buffer structure US and the lower buffer structure LS will be described in more detail with reference to FIGS. 5 to 13.

The upper buffer structure US may be stacked or attached on a top surface of the display panel DP by the second upper adhesive layer 50b. In an embodiment, a polarizing layer POL may be disposed between the upper buffer structure US and the display panel DP. In this case, the upper buffer structure US may be attached or stacked on a top surface of the polarizing layer POL by the second upper adhesive layer 50b.

The polarizing layer POL may be disposed on the touch sensor layer TS to efficiently suppress or reduce reflection of external light caused by the sensor electrodes. In an embodiment, the polarizing layer POL may be provided in the form of a polarizing plate including a polarizer and a protective film formed on top and/or bottom surfaces of the polarizer. The polarizer may include an iodine-stained polyvinyl alcohol (“PVA”) film. The polarizer may be stretched in a predetermined axial direction to provide polarization properties by an orientation of iodine molecules.

A protective film PL may be attached or stacked on the upper buffer structure US. The protective film PL may be combined with the upper buffer structure US by the first upper adhesive layer 50a.

The protective film PL may include a glass film or a transparent plastic film. In an embodiment, the protective film PL may be included in the window structure WS of FIG. 1.

A supporting plate SPL may be disposed under the display panel DP. The supporting plate SPL may face the display panel DP with the lower buffer structure LS interposed therebetween.

The supporting plate SPL may include a resin plate such as polyurethane, a ceramic plate, or an organic-inorganic composite plate. In an embodiment, the supporting plate SPL may include a reinforced plastic including inorganic fibers such as carbon fibers. An entirety of the rigidity of the display device DD may be maintained by the supporting plate SPL.

A functional layer FL may be disposed under the supporting plate SPL, and a bottom plate BPL may be disposed under the functional layer FL. The functional layer FL may include a sensor layer such as a digitizer, a functional sheet such as a heat dissipation sheet, or the like. In an embodiment, the bottom plate BPL may include a metal plate such as a stainless steel plate, e.g., steel use stainless (“SUS”) plate, for example. In an embodiment, the bottom plate BPL may be provided as a fixing plate or frame of a main board, a battery, or the like.

A third adhesive layer 70 may be formed between the supporting plate SPL and the functional layer FL to combine the supporting plate SPL and the functional layer FL with each other. A fourth adhesive layer 80 may be formed between the functional layer FL and the bottom plate BPL to combine the functional layer FL and the bottom plate BPL with each other.

In an embodiment, the display device DD may include a folding area FA. Openings OP may be defined in a portion of the supporting plate SPL of the folding area FA, and thus flexibility in the folding area FA may be improved. The openings OP may have a hole shape penetrating the supporting plate SPL. The openings OP may refer to a thin film portion of the supporting plate SPL having a recess shape or a trench shape.

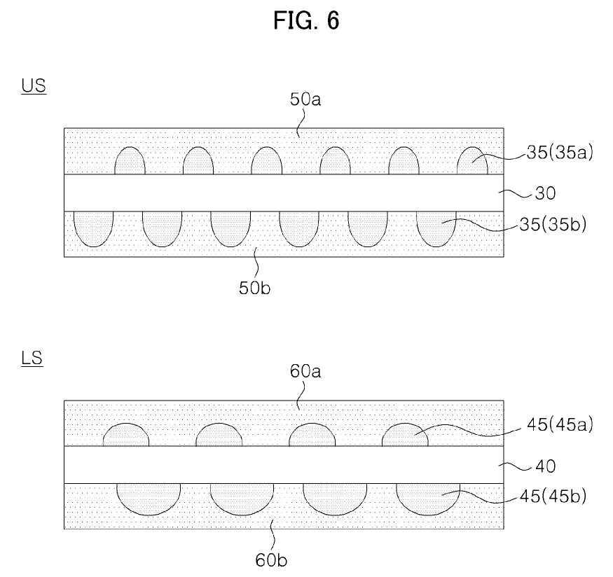

FIGS. 5 and 6 are cross-sectional views illustrating embodiments of buffer structures. FIGS. 5 and 6 each illustrates both the upper buffer structure US and the lower buffer structure LS.

Referring to FIG. 5, the upper buffer structure US may include an upper substrate 30 and upper buffer patterns 35 distributed on the upper substrate 30. The upper buffer patterns 35 may include first upper buffer patterns 35a arranged on a top surface of the upper substrate 30 and second upper buffer patterns 35b arranged on a bottom surface of the upper substrate 30.

The lower buffer structure LS may include a lower substrate 40 and lower buffer patterns 45 distributed on the lower substrate 40. The lower buffer patterns 45 may include first lower buffer patterns 45a arranged on a top surface of the lower substrate 40 and second lower buffer patterns 45b arranged on a bottom surface of the lower substrate 40.

The upper substrate 30 and the lower substrate 40 may include a glass film or a transparent resin film. In an embodiment, the transparent resin film may include a polyester resin such as polyethylene terephthalate, polyethylene isophthalate, polyethylene naphthalate, polybutylene terephthalate, or the like; a cellulose resin such as diacetylcellulose, triacetylcellulose, or the like; a polycarbonate resin; an acrylic resin such as polymethyl(meth)acrylate, polyethyl(meth)acrylate, or the like; a styrene resin; a polyolefin resin such as polyethylene, polypropylene, a cycloolefin resin, or the like; an amide resin; a vinyl alcohol resin; a vinylidene chloride resin; a vinylbutyral resin; an epoxy resin; an urethane resin; a silicone resin; a rubber or elastomer-based resin, or the like, for example. These may be used alone or in a combination of two or more therefrom.

The buffer patterns 35 and 45 may include or consist of elastic embossing resin patterns. The buffer patterns 35 and 45 may be island-shaped patterns separated from each other and distributed on the surfaces of the substrates 30 and 40.

In an embodiment, the buffer patterns 35 and 45 may include an optically clear resin (“OCR”)-based adhesive resin material. In an embodiment, the buffer patterns 35 and 45 may include an acrylic resin, a silicone resin, or an acrylic-urethane resin, for example.

In an embodiment, the above-described resin material may be applied in a pattern form by an inkjet printing, a jet dispensing, a slit coating, or the like, on the surfaces of the substrates 30 and 40. Thereafter, the buffer patterns 35 and 45 may be formed through a thermal curing or an ultraviolet (“UV”) curing.

In an embodiment of the disclosure, a storage modulus (G′) of the upper buffer patterns 35 may be less than a storage modulus (G′) of the lower buffer patterns 45. In an embodiment, the storage modulus of the upper buffer patterns 35 may be about 0.1 megapascal (MPa) or less, and the storage modulus of the lower buffer patterns 45 may be about 0.4 MPa or more at 25 degrees Celsius (° C).

In an embodiment, the storage modulus of the upper buffer patterns 35 may be about 0.05 MPa or less, about 0.04 MPa or less, about 0.03 MPa or less, or about 0.02 MPa or less. In an embodiment, the storage modulus of the upper buffer patterns 35 may be about 0.001 MPa or more, about 0.002 MPa or more, or about 0.005 MPa or more, for example.

In an embodiment, the storage modulus of the lower buffer patterns 45 may be in a range from about 0.4 MPa to about 0.8 MPa, from about 0.4 MPa to about 0.7 MPa, from about 0.4 MPa to about 0.6 MPa, or from about 0.4 MPa to about 0.5 MPa.

The storage modulus of the buffer patterns 35 and 45 may be a value measured at 25 oC. In an embodiment, the storage modulus may be measured using a dynamic mechanical analyzer (“DMA”) while increasing a temperature by 3 oC per minute in a temperature range of -50 oC to 150 oC, for example.

In an embodiment, an adhesive force (e.g., adhesive force to the upper substrate 30) of the upper buffer patterns 35 may be greater than an adhesive force (e.g., adhesive force to the lower substrate 40) of the lower buffer patterns 45.

In an embodiment, the adhesive force measured at 25oC of the upper buffer patterns 35 may be in a range from about 900 gram-force per inch (gf/inch) to about 1,500 gf/inch, from about 900 gf/inch to about 1,300 gf/inch, or from about 900 gf/inch to 1,100 gf/inch. In an embodiment, the adhesive force measured at 25oC of the lower buffer patterns 35 may be in a range from about 100 gf/inch to about 1,100 gf/inch, from 100 gf/inch to about 500 gf/inch, or from about 100 gf/inch to about 200 gf/inch.

In an embodiment, the adhesive force (unit: gf/inch) may be measured as a force measured by fixing the buffer structure to an adhesive force measurement device, e.g., TA Instrument, and then peeling-off the buffer patterns from the substrate at 25oC, a peeling rate of 300 mm/min, and a peeling angle of 180o, for example.

In an embodiment, the storage modulus and/or the adhesive force of the upper buffer patterns 35 and the lower buffer patterns 45 may be adjusted to the above-described range by adjusting a type, a thermal curing temperature, a photo-curing time, or the like of the OCR resin.

As described above, the buffer patterns having a relatively low storage modulus may be distributed in the upper buffer structure US stacked on the display panel DP. Accordingly, damping properties with respect to external impact, stamping, pressing, etc., applied to the window structure WS or the protective film PL may be improved. Further, impact dispersion properties may be improved through the upper buffer structure US, and an interlayer adhesion may be maintained.

The buffer patterns having a relatively high storage modulus may be distributed in the lower buffer structure LS disposed under the display panel DP. Thus, the entirety of the rigidity or hardness of the display device DD may be maintained or improved while maintaining shock absorption properties through the lower buffer structure LS. In an embodiment, deformation of the display panel DP caused by collision of an external object may be effectively suppressed through the lower buffer structure LS, for example.

The upper buffer structure US may further include the upper adhesive layers 50a and 50b covering the upper buffer patterns 35. In an embodiment, the first upper adhesive layer 50a may be formed on a top surface of the upper substrate 30 to cover the first upper buffer patterns 35a. The second upper adhesive layer 50b may be formed on a bottom surface of the upper substrate 30 to cover the second upper buffer patterns 35b.

The lower buffer structure LS may further include the lower adhesive layers 60a and 60b covering the lower buffer patterns 45. In an embodiment, the first lower adhesive layer 60a may be formed on a top surface of the lower substrate 40 to cover the first lower buffer patterns 45a. The second lower adhesive layer 60b may be formed on a bottom surface of the lower substrate 40 to cover the second lower buffer patterns 45b.

The upper and lower adhesive layers 50a, 50b, 60a and 60b may include, e.g., a pressure-sensitive adhesive (“PSA”) including an acrylic resin or a silicone resin.

A thickness of the buffer patterns 35 and 45 may be 70% or less of a thicknesses of the upper and lower adhesive layers 50a, 50b, 60a and 60b. In an embodiment, the thickness of the buffer patterns 35 and 45 may be in a range from 40% to 70%, or from 50% to 70% of the thickness of the upper and lower adhesive layers 50a, 50b, 60a and 60b, for example. In the above range, the adhesive forces of the upper and lower buffer structures US and LS may be stably maintained while sufficiently implementing elastic modulus properties of the buffer patterns 35 and 45.

In an embodiment, each of the upper and lower adhesive layers 50a, 50b, 60a and 60b may have a thickness from about 25 micrometers (μm) to about 100 μm, from about 50 μm to about 100 μm, or from about 70 μm to about 100 μm.

In an embodiment, a width W1 of the upper buffer pattern 35 may be less than a width W2 of the lower buffer pattern 45. A thickness T1 of the upper buffer pattern 35 may be greater than a thickness T2 of the lower buffer pattern 45. Accordingly, shock damping properties through the upper buffer patterns 35 and rigidity improvement through the lower buffer patterns 45 may be effectively implemented.

In an embodiment, the width W1 of the upper buffer pattern 35 may be less than or equal to a distance (an interval) D1 between neighboring upper buffer patterns 35. In an embodiment, the width W2 of the lower buffer pattern 45 may be less than or equal to a distance (an interval) D2 between neighboring lower buffer patterns 45.

In an embodiment, the width W1 of the upper buffer pattern 35 may be less than the distance D1 between neighboring upper buffer patterns 35. In an embodiment, the width W2 of the lower buffer pattern 45 may be less than the distance D2 between neighboring lower buffer patterns 45.

As described above, the distance between the buffer patterns 35 and 45 may be properly maintained, thereby increasing adhesion between the adhesive layers 50a, 50b, 60a and 60b and the buffer patterns 35 and 45.

Referring to FIG. 6, sizes of the buffer patterns 35 and 45 in the upper buffer structure US and the lower buffer structure LS may be appropriately changed.

In the upper buffer structure US, sizes, intervals, locations, or the like, of the first upper buffer patterns 35a and the second upper buffer patterns 35b may be changed to be different from each other. In an embodiment, a size (a width or a height) of the second upper buffer patterns 35b may be adjusted to be greater than a size of the first upper buffer patterns 35a. In an embodiment, an interval distance or a pitch of the first upper buffer patterns 35a may be adjusted to be greater than an interval or a pitch of the second upper buffer patterns 35b.

In the lower buffer structure LS, sizes, intervals, locations, or the like, of the first lower buffer patterns 45a and the second lower buffer patterns 45b may be changed to be different from each other. In an embodiment, a size of the second lower buffer patterns 45b may be adjusted to be greater than a size of the first upper buffer patterns 45a. In an embodiment, an interval or a pitch of the first lower buffer patterns 45a may be adjusted to be greater than an interval or a pitch of the second lower buffer patterns 45b.

In an embodiment, storage modulus of the first upper buffer pattern 35a and the second upper buffer pattern 35b may be adjusted to be different from each other. In an embodiment, a storage modulus of the first upper buffer pattern 35a may be greater than a storage modulus of the second upper buffer pattern 35b, for example.

In an embodiment, storage modulus of the first lower buffer pattern 45a and the second lower buffer pattern 45b may be adjusted to be different from each other. In an embodiment, a storage modulus of the first lower buffer pattern 45a may be greater than a storage modulus of the second lower buffer pattern 45b, for example.

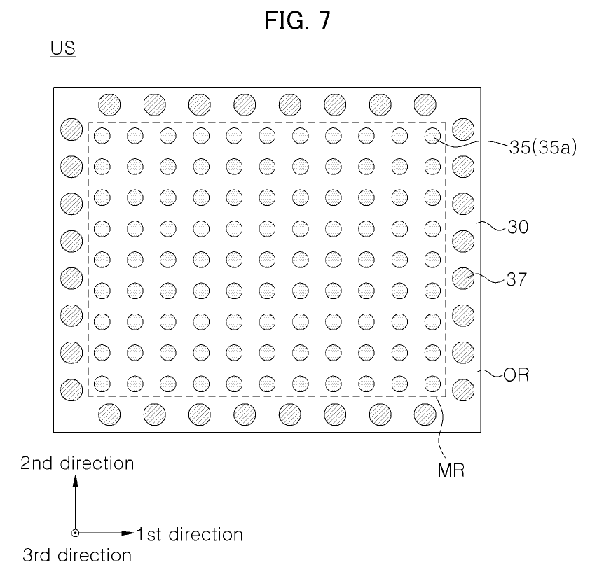

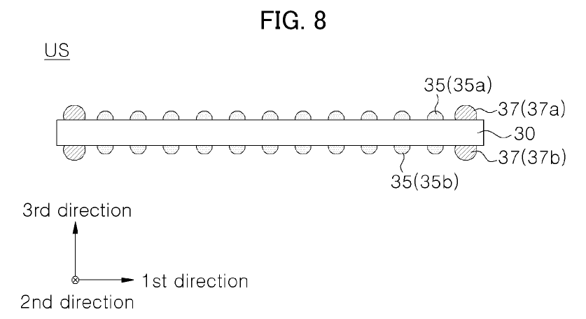

FIGS. 7 and 8 are a plan view and a cross-sectional view, respectively, illustrating embodiments of an upper buffer structure.

Referring to FIGS. 7 and 8, the upper buffer structure US may further include sub-upper buffer patterns 37 arranged at a peripheral portion or an edge portion of a surface of the upper substrate 30. In an embodiment, a top surface or a bottom surface of the upper substrate 30 may include a main region MR including a central region, and an outer region OR surrounding the main region MR, for example.

The upper buffer patterns 35 may be arranged on the main region MR, and the sub-upper buffer patterns 37 may be arranged on the outer region OR. In an embodiment, the outer region OR may include an entirety of the peripheral portion of the upper substrate 30, and the sub-upper buffer patterns 37 may be arranged to be spaced apart from each other throughout the outer region OR, for example.

The sub-upper buffer patterns 37 may include first sub-upper buffer patterns 37a and second sub-upper buffer patterns 37b. The first sub-upper buffer patterns 37a may be arranged on the top surface of the upper substrate 30 together with the first upper buffer patterns 35a. The second sub-upper buffer patterns 37b may be arranged on the bottom surface of the upper substrate 30 together with the second upper buffer patterns 35b.

In an embodiment, a storage modulus of the sub-upper buffer patterns 37 may be greater than the storage modulus of the upper buffer patterns 35. In an embodiment, a width of each of the sub-upper buffer patterns 37 may be greater than a width of each of the upper buffer patterns 35.

In an embodiment, a thickness of each of the sub-upper buffer patterns 37 may be greater than a thickness of each of the upper buffer patterns 35. In an embodiment, a thickness of each of the sub-upper buffer patterns 37 may be less than a thickness of each of the upper buffer patterns 35.

As described above, the sub-upper buffer patterns 37 may be added to enhance resistance and stability against stress and shock generated at an upper edge of the display device DD. In the main region MR, shock damping and dispersion properties may be improved through the upper buffer patterns 35.

The number of the upper buffer patterns 35 arranged on the main region MR and having a relatively small storage modulus may be greater than the number of the sub-upper buffer patterns 37 arranged on the outer region OR and having a relatively large storage modulus. In an embodiment, a ratio of the number of the upper buffer patterns 35 to the number of sub-upper buffer patterns 37 may be 3 or more, 4 or more, or 5 or more. In an embodiment, the ratio of the number of the buffer patterns may be in a range from 3 to 10, from 4 to 10, or from 5 to 10, for example.

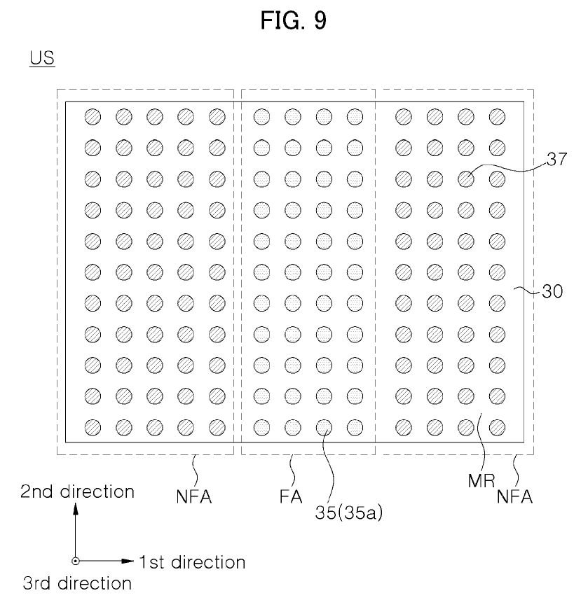

FIG. 9 is a plan view illustrating embodiments of an upper buffer structure.

Referring to FIG. 9, as described above, the display device DD or the display panel DP may include the folding area FA. A pair of non-folding areas NFA may face each other with the folding area FA interposed therebetween.

In an embodiment, the upper buffer patterns 35a may be arranged on a surface of the upper substrate 30 in the folding area FA. The sub-upper buffer patterns 37 may be arranged on a surface of the upper substrate 30 in the non-folding area NFA. As described with reference to FIGS. 7 and 8, the sub-upper buffer patterns 37 may have the storage modulus greater than that of the upper buffer patterns 35.

The upper buffer patterns 35 having a relatively low storage modulus may be distributed in the upper buffer structure US of the folding area FA to reduce folding resistance or folding repulsive force in the folding area FA. The sub-upper buffer patterns 37 having a relatively high storage modulus may be distributed in the upper buffer structure US of the non-folding area NFA to easily achieve impact resistance and mechanical stability in the non-folding area NFA.

As described above, the sub-upper buffer patterns 37 may include the first sub-upper buffer patterns 37a and the second sub-upper buffer patterns 37b formed on the top and bottom surfaces of the upper substrate 30, respectively.

In an embodiment, the sub-upper buffer patterns 37 described with reference to FIGS. 7 to 9 may have a storage modulus in a range substantially the same as or similar to that of the lower buffer patterns 45 included in the lower buffer structure LS.

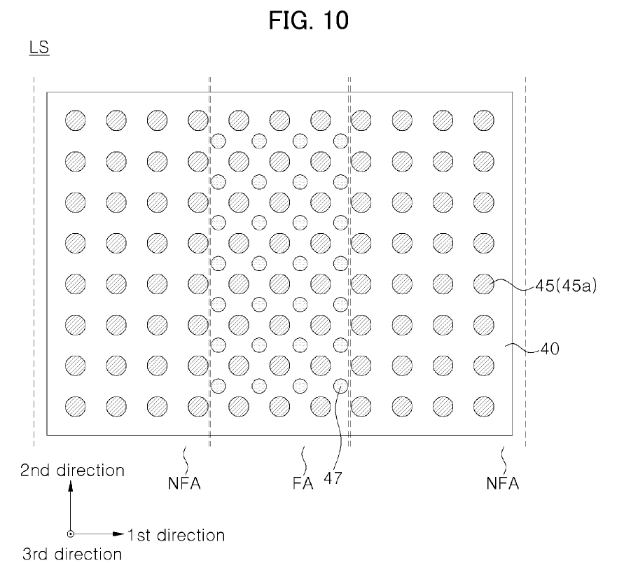

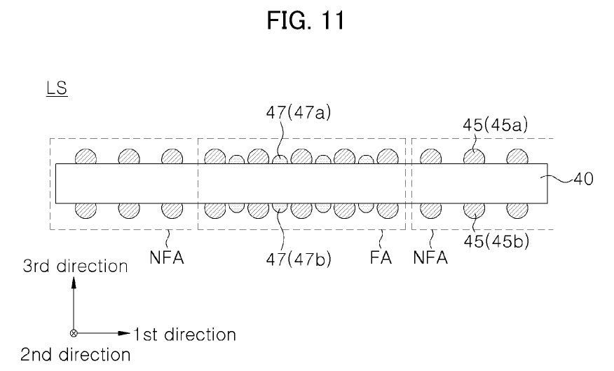

FIGS. 10 and 11 are a plan view and a cross-sectional view, respectively, illustrating embodiments of a lower buffer structure.

Referring to FIG. 10, the lower buffer patterns 45 and sub-lower buffer patterns 47 may be distributed together in the folding area FA of the lower buffer structure LS.

A storage modulus of the sub-lower buffer patterns 47 may be less than the storage modulus of the lower buffer patterns 45. In an embodiment, the sub-lower buffer patterns 47 may have a storage modulus in a range substantially the same as or similar to that of the upper buffer patterns 35 included in the upper buffer structure US, for example.

The sub-lower buffer patterns 47 having a relatively small storage modulus may be distributed in the lower buffer structure LS of the folding area FA, so that excessive increase in folding resistance or folding repulsion in the folding area FA may be suppressed.

As illustrated in FIG. 10, only the lower buffer patterns 45 having a relatively large storage modulus may be distributed in the lower buffer structure LS of the non-folding area NFA to maintain a supporting rigidity through the lower buffer structure LS.

Referring to FIG. 11, the lower buffer patterns 45 and the sub-lower buffer patterns 47 may be alternately and repeatedly arranged in the folding area FA along the first direction. In an embodiment, the sub-lower buffer patterns 47 may include first sub-lower buffer patterns 47a on an upper surface of the lower substrate 40 and second sub-lower buffer patterns 47b on a lower surface of the lower substrate 40, for example.

In an embodiment, as illustrated in FIG. 10, the lower buffer patterns 45 and the sub-lower buffer patterns 47 may be alternately and repeatedly arranged in a zigzag direction in the folding area FA.

In an embodiment, a distance between neighboring lower buffer patterns 45 may be greater than a width of each of the sub-lower buffer patterns 47. Accordingly, decrease in adhesion and increase in folding repulsion in the folding area FA may be additionally suppressed.

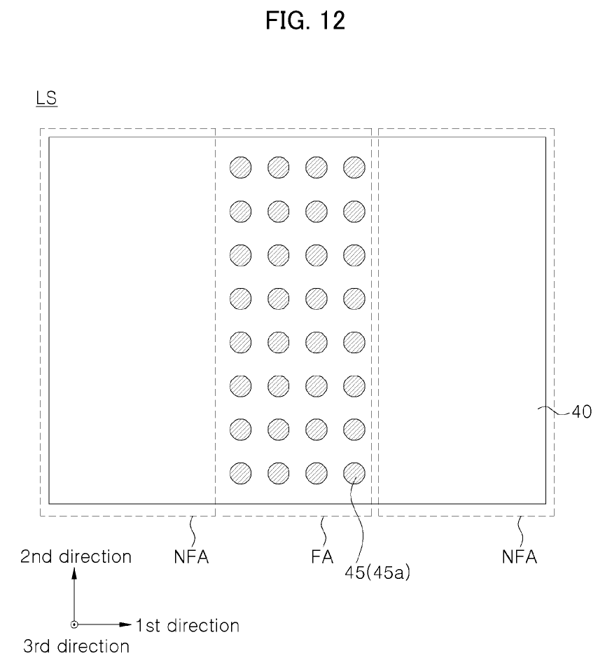

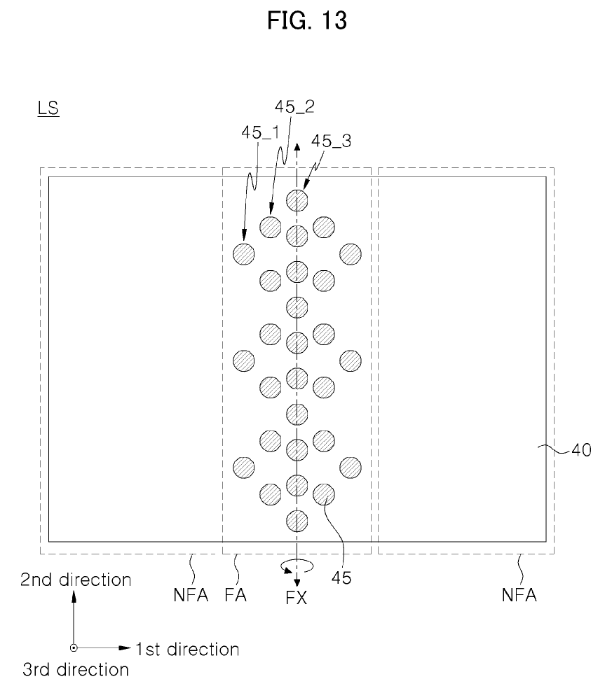

FIGS. 12 and 13 are plan views illustrating embodiments of a lower buffer structure.

Referring to FIGS. 12 and 13, the lower buffer patterns 45 may be selectively arranged in the folding area FA in the lower buffer structure LS. Accordingly, a decrease in rigidity at a lower portion of the display device DD due to repetitive folding in the folding area FA may be buffered or prevented.

As illustrated in FIG. 12, a plurality of lower buffer patterns 45 may be arranged in the second direction to define lower buffer pattern columns. A plurality of the lower buffer pattern columns may be arranged in the first direction in the folding area FA.

As illustrated in FIG. 13, the number of the lower buffer patterns 45 may be decreased from a central region of the folding area FA to a side region next (adjacent) to the non-folding area NFA. The central region may include a folding axis FX.

In an embodiment, the lower buffer pattern columns may include a first lower buffer pattern column 45_1, a second lower buffer pattern column 45_2, and a third lower buffer pattern column 45_3, sequentially away from the non-folding area NFA in the first direction, for example. In an embodiment, the third lower buffer pattern column 45_3 may overlap the folding axis FX of the folding area FA, for example.

The number of the lower buffer patterns 45 included in the first lower buffer pattern column 45_1 may be less than the number of the lower buffer patterns 45 included in the second lower buffer pattern column 45_2. The number of the lower buffer patterns 45 included in the second lower buffer pattern column 45_2 may be less than the number of the lower buffer patterns 45 included in the third lower buffer pattern column 45_3.

As described above, folding resistance or folding repulsion may be reduced by reducing the number of the lower buffer patterns 45 on the side portion of the folding area FA.

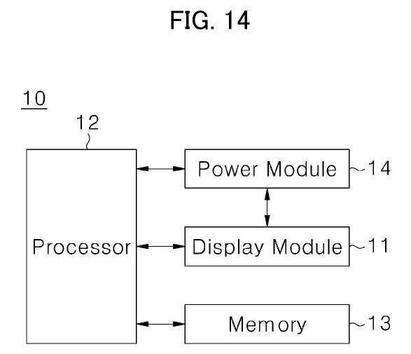

FIG. 14 is a block diagram of an embodiment of an electronic device.

Referring to FIG. 14, an electronic device 10 in an embodiment may include a display module 11, a processor 12, a memory 13 and a power module 14.

The processor 12 may include a central processing unit (“CPU”), an application processor (“AP”), a graphic processing unit (“GPU”), a communication processor (“CP”), an image signal processor (“ISP”) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power desired for the operation of the electronic device 10.

At least one of components of the electronic device 10 as described above may be included in the display device according to the above-described embodiments. Additionally, some of individual modules functionally included in one module may be included in the display device, and others may be provided separately from the display device. In an embodiment, the display module 11 may include the display device, and the processor 12, the memory 13 and the power module 14 may be provided in the form of another device in the electronic device 10 different from the display device, for example.

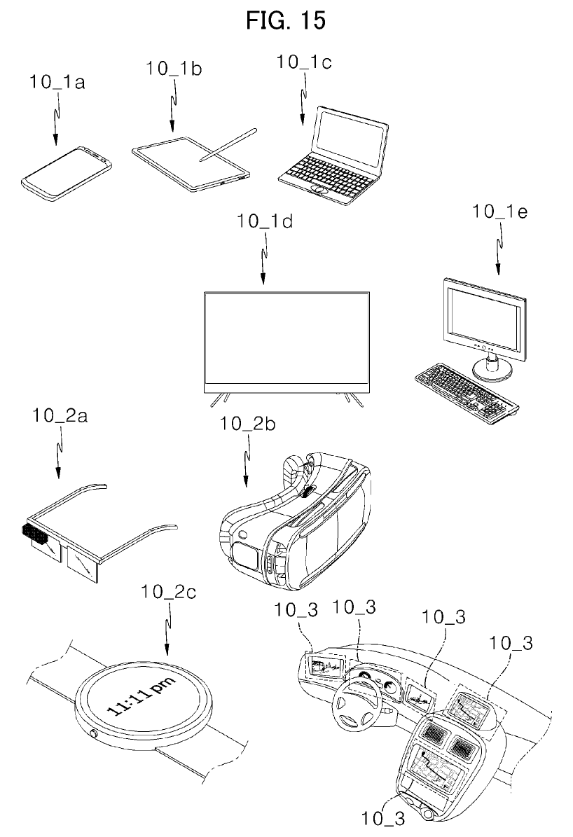

FIG. 15 is a schematic diagram of embodiments of electronic devices.

Referring to FIG. 15, non-limiting embodiments of various electronic devices to which the display device according to the above-described embodiments is applied include an electronic device for displaying an image such as a smartphone 10_1a, a tablet personal computer 10_1b, a laptop 10_1c, a television (“TV”) 10_1d, a desk monitor 10_1e, or the like; a wearable electronic device including a display module such as smart glasses 10_2a, a head mounted display 10_2b, a smart watch 10_2c, or the like; a vehicle electronic device 10_3 including a display module such as a center information display (“CID”) disposed at a vehicle instrument panel, a center fascia, a dashboard, etc., a head-up display, a room mirror display, or the like. The electronic device may include a virtual reality glass or an augmented reality glass.

What is claimed is:

1. A display device comprising:
a display panel;
an upper buffer structure on the display panel, the upper buffer structure comprising:
an upper substrate; and
an upper buffer patterns arranged on a surface of the upper substrate; and
a lower buffer structure under the display panel, the lower buffer structure comprising:
a lower substrate; and
lower buffer patterns arranged on a surface of the lower substrate and having a storage modulus greater than a storage modulus of the upper buffer patterns.

2. The display device of claim 1, wherein the upper buffer patterns comprise first upper buffer patterns arranged on a top surface of the upper substrate, and second upper buffer patterns arranged on a bottom surface of the upper substrate.

3. The display device of claim 2, wherein a width or an interval of the first upper buffer patterns is different from a width or an interval of the second upper buffer patterns.

4. The display device of claim 1, wherein the lower buffer patterns comprise first lower buffer patterns arranged on a top surface of the lower substrate, and second lower buffer patterns arranged on a bottom surface of the lower substrate.

5. The display device of claim 4, wherein a width , or an interval of the first lower buffer patterns is different from a width or an interval of the second lower buffer patterns.

6. The display device of claim 1, wherein a width of the upper buffer patterns is less than a width of the lower buffer patterns.

7. The display device of claim 1, wherein a thickness of the upper buffer patterns is greater than a thickness of the lower buffer patterns.

8. The display device of claim 1, wherein an interval between the upper buffer patterns is equal to or greater than a width of each of the upper buffer patterns.

9. The display device of claim 1, wherein an interval between the lower buffer patterns is equal to or greater than a width of each of the lower buffer patterns.

10. The display device of claim 1, wherein the upper buffer structure further comprises sub-upper buffer patterns arranged on an outer portion of the surface of the upper substrate, and a storage modulus of the sub-upper buffer patterns is greater than a storage modulus of the upper buffer patterns.

11. The display device of claim 1, wherein the display device has a folding area and a non-folding area,
the upper buffer structure further comprises sub-upper buffer patterns arranged on a portion of the surface of the upper substrate in the non-folding area, and
the upper buffer patterns are arranged on a portion of the surface of the upper substrate in the folding area, and have the storage modulus less than a storage modulus of the sub-upper buffer patterns.

12. The display device of claim 1, wherein the display device has a folding area and a non-folding area,
the lower buffer structure further comprises sub-lower buffer patterns arranged on a portion of the surface of the lower substrate in the folding area together with the lower buffer patterns, and
a storage modulus of the sub-lower buffer patterns is less than the storage modulus of the lower buffer patterns.

13. The display device of claim 1, wherein the display device has a folding area and a non-folding area, and
the lower buffer patterns are arranged on a portion of the surface of the lower substrate in the folding area.

14. The display device of claim 13, wherein the number of the lower buffer patterns arranged on a folding axis of the folding area is greater than the number of the lower buffer patterns arranged on a side portion of the folding area next to the non-folding area.

15. The display device of claim 1, wherein the storage modulus of the upper buffer patterns at 25 degrees Celsius is 0.1 megapascal or less, and the storage modulus of the lower buffer patterns at 25 degrees Celsius is 0.4 megapascal or greater.

16. A display device comprising:
a display panel;
an upper buffer structure on the display panel, the upper buffer structure comprising:
an upper substrate;
upper buffer patterns arranged on a surface of the upper substrate; and
sub-upper buffer patterns arranged on the surface of the upper substrate together with the upper buffer patterns and having a storage modulus different from a storage modulus of the upper buffer patterns; and
a lower buffer structure under the display panel, the lower buffer structure comprising:
a lower substrate;
lower buffer patterns arranged on a surface of the lower substrate; and
sub-lower buffer patterns arranged on the surface of the lower substrate together with the lower buffer patterns and having a storage modulus different from a storage modulus of the lower buffer patterns.

17. The display device of claim 16, wherein the sub-upper buffer patterns are arranged on an outer portion of the surface of the upper substrate, and have the storage modulus greater than the storage modulus of the upper buffer patterns.

18. The display device of claim 16, wherein the display device has a folding area and a non-folding area,
the sub-lower buffer patterns are arranged on a portion of the surface of the lower substrate in the folding area together with the lower buffer patterns, and
the storage modulus of the sub-lower buffer patterns is less than the storage modulus of the lower buffer patterns.

19. An electronic device comprising:
a display device comprising:
a display panel;
an upper buffer structure on the display panel, the upper buffer structure comprising:
an upper substrate; and
an upper buffer patterns arranged on a surface of the upper substrate; and
a lower buffer structure under the display panel, the lower buffer structure comprising:
a lower substrate; and
lower buffer patterns arranged on a surface of the lower substrate and having a storage modulus greater than a storage modulus of the upper buffer patterns;
a memory; and
a processor executing data included in the memory to control an operation of the display device.

20. The electronic device of claim 19, wherein the electronic device includes virtual reality or augmented reality glasses, a smartphone, a tablet personal computer, a laptop, a television, a desk monitor, smart glasses, a head-mounted display, a smart watch, or a vehicle display.
